(19) United States
(12) Patent Application Publication
(10) Pub. No.: US 2026/0101784 A1
(43) Pub. Date: Apr. 9, 2026

(54) SEMICONDUCTOR PACKAGE

(71) Applicant: Samsung Electronics Co., Ltd., Suwon-si (KR)

(72) Inventors: Dowan KIM, Suwon-si (KR); Unbyoung KANG, Suwon-si (KR); Seokbong PARK, Suwon-si (KR); Hakyeong LEE, Suwon-si (KR)

(73) Assignee: Samsung Electronics Co., Ltd., Suwon-si (KR)

(21) Appl. No.: 19/093,531

(22) Filed: Mar. 28, 2025

(30) Foreign Application Priority Data
Oct. 8, 2024 (KR) 10-2024-0136435

(51) Int. Cl. H01L 23/538; H01L 25/07

(52) U.S. Cl. CPC H10W 70/65; H10W 70/611; H10W 90/00; H10W 90/401

(57) ABSTRACT

A semiconductor package includes a lower redistribution structure including a lower insulating layer, a UBM structure, and lower redistribution layers, a bridge die electrically connected to the lower redistribution layers, a bonding pad, an encapsulant, and a conductive post. The UBM structure includes a bonding portion in contact with the bonding pad, the bonding pad having an increasing width as a level thereof decreases, a pad portion connected to the bonding portion below the bonding portion, the pad portion disposed in the lower insulating layer, and a via portion connected to the pad portion below the pad portion. A width of an upper surface of the bonding portion is less than a width of the bonding pad. A width of a lower surface of the conductive post is less than a width of the bonding pad.

### CROSS-REFERENCE TO RELATED APPLICATION(S)

This application claims benefit of priority to Korean Patent Application No. 10-2024-0136435 filed on Oct. 8, 2024 in the Korean Intellectual Property Office, the disclosure of which is incorporated herein by reference in its entirety.

### BACKGROUND

The present inventive concepts relate to a semiconductor package.

Electronic devices have been reduced in size and weight in accordance with the development of the electronics industry and user demand, and semiconductor packages used in the electronic devices have been implemented to have high performance and high capacitance along to compensate for the reduction in size and weight. In order to implement high performance and high capacitance along with reduction in size and weight, a semiconductor package structure including an interposer, interconnecting a plurality of semiconductor chips, have been continuously researched and developed.

### SUMMARY

An aspect of the present inventive concepts provides a semiconductor package having a simplified process and improved reliability.

According to an aspect of the present inventive concepts, there is provided a semiconductor package including a lower redistribution structure including a lower insulating layer, a under bump metallization (UBM) structure, and lower redistribution layers, the UBM structure passing through the lower insulating layer, and the lower redistribution layers on and in the lower insulating layer; a bridge die above and electrically connected to the lower redistribution layers; a bonding pad above the UBM structure; an encapsulant above the lower insulating layer and covering at least a portion of each of the bridge die, the lower redistribution layers, the UBM structure, and the bonding pad; and a conductive post passing through the encapsulant, the conductive post above and connected to the bonding pad. The UBM structure may include a bonding portion in contact with the bonding pad, the bonding portion having an increasing width with distance from the bonding pad, a pad portion below and connected to the bonding portion below the bonding portion, and a via portion below and connected to the pad portion below the pad portion. A width of an upper surface of the bonding portion may be less than a width of the bonding pad. A width of a lower surface of the conductive post may be less than a width of the bonding pad.

According to an aspect of the present inventive concepts, there is provided a semiconductor package including a bridge die; a lower insulating layer below the bridge die; lower redistribution layers including external redistribution layers, internal redistribution layers, and connection redistribution layers, the external redistribution layers on the lower insulating layer, the internal redistribution layers in the lower insulating layer, and the connection redistribution layers connected to the bridge die and a under bump metallization (UBM) structure spaced apart from the bridge die in a horizontal direction, at least portion of the UBM structure passing through the lower insulating layer. Each of the external redistribution layers may have a lower surface in contact with an upper surface of the lower insulating layer, and has an increasing width with distance approaching the upper surface of the lower insulating layer. Each of the internal redistribution layers may have an upper surface at a same or lower level as the upper surface of the lower insulating layer, and each of the internal redistribution layers has a decreasing width with distance from the upper surface of the lower insulating layer.

According to an aspect of the present inventive concepts, there is provided a semiconductor package including a package substrate; semiconductor chips; and an interposer substrate between the package substrate and the semiconductor chips, the interposer substrate electrically connecting the semiconductor chips to the package substrate. The interposer substrate may include a lower redistribution structure including a lower insulating layer and a under bump metallization (UBM) structure passing through the lower insulating layer, a bridge die on the lower redistribution structure spaced apart from the UBM structure, the bridge die electrically connected to the semiconductor chips, an encapsulant covering at least a portion of the bridge die and at least a portion of the UBM structure, on the lower redistribution structure, an upper redistribution structure on the encapsulant, the upper redistribution structure including upper redistribution layers electrically connected to the semiconductor chips, and a conductive post passing through the encapsulant, the conductive post electrically connecting the upper redistribution layers and the UBM structure. The UBM structure may include a first portion at a level closer to an upper surface of the lower insulating layer than to an upper surface of the UBM structure, the first portion having a maximum width in a horizontal direction, a second portion above the first portion and having a width decreasing with distance from the first portion, and a third portion below the first portion and having a width decreasing with distance from the first portion.

According to an aspect of the present inventive concepts, there is provided a method of forming a semiconductor package, the method including forming a lower insulating layer on a carrier such that the lower insulating layer defines a plurality of holes including holes penetrating to a first depth and holes penetrating to a second depth deeper than the first depth; forming a preliminary redistribution layer on the lower insulating layer such that the preliminary redistribution layer fills the plurality of holes; forming a first mask on the preliminary redistribution layer such that the first mask exposes portions of the preliminary redistribution layer in the holes penetrating to the first depth in a center portion of the preliminary redistribution layer and in at least a portion of the holes penetrating to the second depth; forming bonding pads on the portions of the preliminary redistribution layer exposed by the first mask; forming a lower redistribution layers by removing portions of the preliminary redistribution layer exposed by the bonding pads; forming a second mask on the preliminary redistribution layer, the second mask covering the bonding pads over the holes penetrating to the first depth and exposing the bonding pads over the holes penetrating to the second depth; forming conductive posts on the bonding pads exposed by the second mask; removing the second mask; bonding a bridge die on to the bonding pads over the holes penetrating to the first depth in the central region; and forming a redistribution structure over the conductive posts and the bride die.

The method may further include removing the carrier such that the portion of the lower redistribution in the holes penetrating to the second depth are exposed; and forming connection conductors on the exposed portions of the lower redistribution corresponding to the holes penetrating the second depth.

The removing the carrier may include forming an under bump metallization (UBM) structure from the exposed portions of the lower redistribution corresponding to the holes penetrating the second depth.

The forming the lower redistribution layers may include forming the lower redistribution layers such that the UBM structure includes a bond portion above the lower insulating layer, a pad portion between the bond portion and the first depth, and a via portion between the first depth and the second depth.

The method may further comprise forming an encapsulant covering at least a portion of each of the bridge die, the lower redistribution layers, the UBM structure, and the bonding pad.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a schematic plan view of a semiconductor package according to some example embodiments;

FIG. 2 is a schematic cross-sectional view of a semiconductor package according to some example embodiments;

FIGS. 3A and 3B are schematic partially enlarged views of a semiconductor package according to some example embodiments;

FIGS. 4A and 4B are schematic partially enlarged views of a semiconductor package according to some example embodiments;

FIGS. 5A to 5F are schematic cross-sectional enlarged views of a semiconductor package according to some example embodiments;

FIG. 6 is a schematic plan view of a semiconductor package according to example embodiments;

FIGS. 7, 8A, 9, 10A, 11A, 12, 13A, 14A, 15, 16, 17, 18, and 19 are cross-sectional views of sequential processes in a method of manufacturing a semiconductor package according to example embodiments; and

FIGS. 8B, 8C, 10B, 10C, 11B, 11C, 13B, 13C, 14B, and 14C are cross-sectional partially enlarged views of sequential processes in a method of manufacturing a semiconductor package according to example embodiments.

### DETAILED DESCRIPTION

Hereinafter, preferred example embodiments of the present inventive concepts will be described with reference to the accompanying drawings. When describing the example embodiments with reference to the accompanying drawings, like reference numerals refer to like elements and a repeated description related thereto may be omitted. In the drawings, sizes of components in the drawings may be exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Hereinafter, the terms such as “top,” “upper portion,” “upper surface,” “above,” “lower,” “lower portion,” “lower surface,” “below,” and “side surface” may be understood as being based on the drawings. However, it will be understood that such spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

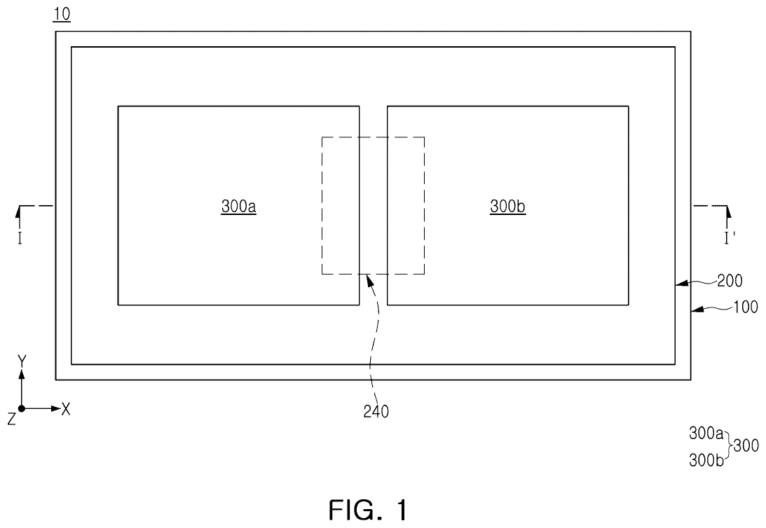

FIG. 1 is a schematic plan view of a semiconductor package according to some example embodiments. For ease of description and clarity of illustration, FIG. 1 illustrates only some components of the semiconductor package.

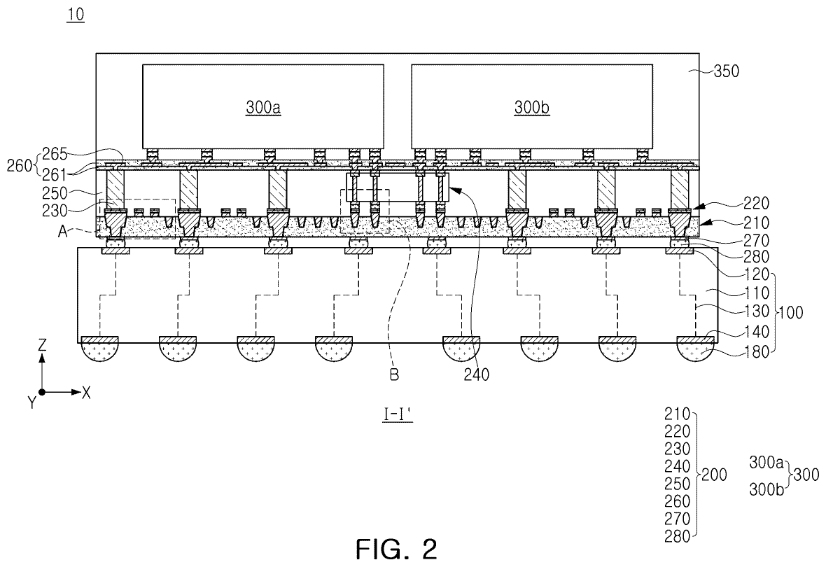

FIG. 2 is a cross-sectional view of a semiconductor package according to some example embodiments. FIG. 2 is a schematic cross-sectional view of the semiconductor package of FIG. 1, taken along line I-I′.

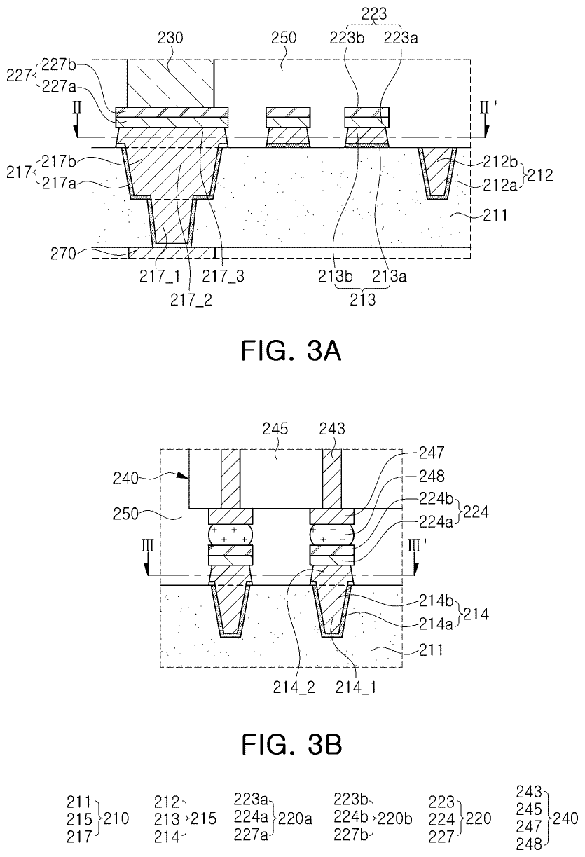

FIGS. 3A and 3B are partially enlarged views of a semiconductor package according to some example embodiments. FIGS. 3A and 3B are enlarged views of region “A” and region “B” of FIG. 2, respectively.

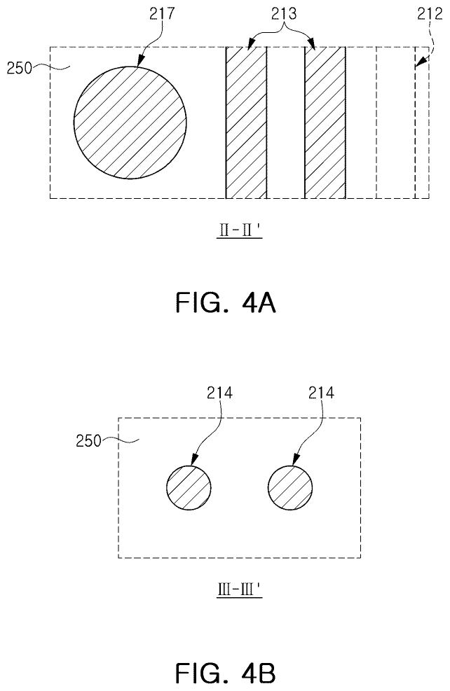

FIGS. 4A and 4B are partially enlarged views of a semiconductor package according to some example embodiments. FIGS. 4A and 4B illustrate a schematic cross-section taken along lines II-II′ and III-III′ of FIGS. 3A and 3B, respectively.

Referring to FIGS. 1 to 4B, a semiconductor package 10 may include a package substrate 100, an interposer substrate 200, and two or more semiconductor chips 300. The semiconductor package 10 may further include an upper encapsulant 350 encapsulating the semiconductor chips 300, on the interposer substrate 200.

The package substrate 100 may be a support substrate on which the interposer substrate 200 and the semiconductor chips 300 are mounted, and may be a substrate for a semiconductor package (such as a printed circuit board (PCB), a ceramic substrate, a glass substrate, a tape interconnection line substrate, and/or the like). The package substrate 100 may include a substrate body 110, upper pads 120, lower pads 140, an interconnection line circuit 130 electrically connecting the upper pads 120 and the lower pads 140 to each other, and external connection terminals 180.

The substrate body 110 may include a material selected based on a type of substrate body 110. For example, when the package substrate 100 is a PCB, the package substrate 100 may be in the form of one or more of a body copper clad laminate or an interconnection line layer additionally stacked on one surface or both surfaces of a copper clad laminate. The substrate body 110 may include an insulating material electrically and physically protecting the interconnection line circuit 130, for example, a thermosetting resin such as an epoxy resin, a thermoplastic resin such as polyimide, a prepreg, an Ajinomoto build-up film (ABF), frame retardant 4 (FR-4), a combination thereof, and/or the like including an inorganic filler and/or a glass fiber (or glass cloth or glass fabric).

The upper pads 120, the lower pads 140, and the interconnection line circuit 130 may form an electrical path connecting a lower surface and an upper surface of the package substrate 100. The interconnection line circuit 130 may include a conductive material (e.g., a zero bandgap conductive material), such as at least one metal and/or an alloy including two or more metals, including one or more of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), etc.

The external connection terminals 170, connected to the lower pads 160, may be disposed on a lower surface of the substrate body 110. The external connection terminals 170 may include, for example, a solder ball. The solder ball may include, for example, tin (Sn), bismuth (Bi), lead (Pb), silver (Ag), alloys thereof, and/or the like.

The interposer substrate 200 may be disposed on the package substrate 100. The interposer substrate 200 may be a support substrate on which the semiconductor chips 300 are mounted, and may be disposed between the package substrate 100 and the semiconductor chips 300. The interposer substrate 200 may include a lower redistribution structure 210, bonding pads 220, conductive posts 230, a bridge die 240, an encapsulant 250, and an upper redistribution structure 260. The interposer substrate 200 may further include lower connection pads 270 and connection conductors 280.

The lower redistribution structure 210 may be a support substrate on which the bridge die 240 is mounted, and may include a lower insulating layer 211, lower redistribution layers 215, and under bump metallization (UBM) structures 217.

The lower insulating layer 211 may have upper and lower surfaces, opposing each other. The lower insulating layer 211 may have, for example, an upper surface extending in an X-direction and a Y-direction. A bridge die 240 may be mounted on an upper surface of the lower insulating layer 211, and a lower surface of the lower insulating layer 211 may oppose the upper surface of the package substrate 100. In some example embodiments, the lower insulating layer 211 may include a thermosetting resin such as an epoxy resin, a thermoplastic resin such as polyimide, a resin (for example, a prepreg, an ABF, FR-4, bismaleimide-triazine (BT), etc.) in which the thermosetting resin or the thermoplastic resin is impregnated with an inorganic filler, and/or the like. In some example embodiments, an organic material may be included. For example, the lower insulating layer 211 may include a photosensitive polymer. The photosensitive polymer may include, for example, at least one of photosensitive polyimide, polybenzoxazole, a phenol-based polymer, and/or a benzocyclobutene-based polymer. In some example embodiments, the lower insulating layer 211 may include a plurality of insulating layers (not illustrated) stacked in a vertical direction (for example, a Z-direction). Depending on a process, the plurality of insulating layers (not illustrated) may have unclear boundaries therebetween.

The lower redistribution layers 215 may be disposed above or in the lower insulating layer 211. The number of the lower redistribution layers 215 may be greater than or less than that illustrated in the drawings. The lower redistribution layers 215 may perform various functions according to a design thereof. For example, the lower redistribution layers 215 may include a ground (GND) pattern, a power (PWR) pattern, and a signal(S) pattern. Here, the signal(S) pattern may be defined as a transmission path of various signals, for example, data signals or the like, excluding the ground (GND) pattern, the power (PWR) pattern, or the like. The lower redistribution layers 215 may include a conductive material (e.g., a zero bandgap conductive material), for example, a metal including copper (Cu), aluminum (Al), silver (Ag), tin (Sn), gold (Au), nickel (Ni), lead (Pb), titanium (Ti), and/or alloys thereof.

The lower redistribution layers 215 may include internal redistribution layers 212 disposed in the lower insulating layer 211, external redistribution layers 213 disposed on the lower insulating layer 211, and connection redistribution layers 214 disposed to overlap the bridge die 240, the connection redistribution layers 214 connected to the bridge die 240.

The internal redistribution layers 212 may be disposed in the lower insulating layer 211 to be adjacent to an upper surface of the lower insulating layer 211. Upper surfaces of the internal redistribution layers 212 may be positioned on a level at a same height or lower than that of the upper surface of the lower insulating layer 211. The upper surfaces of the internal redistribution layers 212 may be in contact with the encapsulant 250, and the bonding pads 220 may be disposed so as to not be on the upper surfaces of the internal redistribution layers 212. The internal redistribution layers 212 may have a linear shape extending in a horizontal direction (X-direction or Y-direction). A width of an upper surface of each of the internal redistribution layers 212 may be greater than a width of a lower surface of each of the internal redistribution layers 212. In the present specification, in the absence of other descriptions, “width” may refer to a width in the horizontal direction (X-direction or Y-direction). When a component extends in the horizontal direction, a width of the component may refer to a width in a different horizontal direction, perpendicular to a direction of extension.

A side cross-section of each of the internal redistribution layers 212 may have a trapezoidal shape having an upper side longer than a lower side thereof. In some example embodiments, a cross-sectional shape of each of the internal redistribution layers 212 may be a trapezoidal shape, and a width of an upper surface of the trapezoidal shape may be greater than a width of a lower surface of the trapezoidal shape. Each of the internal redistribution layers 212 may have an inclined side surface such that a width thereof decreases as a level thereof decreases. In the drawings, only internal redistribution layers 212, adjacent to the upper surface of the lower insulating layer, 211 are illustrated. However, in some example embodiments, the internal redistribution layers 212 may further include internal redistribution layers 212 disposed on different levels in the lower insulating layer 211, and the internal redistribution layers 212, disposed on a lowest level, may be directly connected to the lower connection pads 270. Each of the internal redistribution layers 212 may include an internal conductive layer 212b and an internal seed layer 212a disposed between the internal conductive layer 212b and the lower insulating layer 211. The internal seed layer 212a may cover a side surface and a lower surface of the internal conductive layer 212b. The internal conductive layer 212b may be spaced apart from the lower insulating layer 211 by the internal seed layer 212a. In some example embodiments, the internal seed layer 212a may include copper (Cu), titanium (Ti), or alloys thereof, and the internal conductive layer 212b may include copper (Cu).

The external redistribution layers 213 may be disposed on the upper surface of the lower insulating layer 211. A lower surface of each of the external redistribution layers 213 may be in contact with the upper surface of the lower insulating layer 211, and may be coplanar with the upper surface of the lower insulating layer 211. In some example embodiments, at least a portion of the external redistribution layers 213 may be deposited as to not overlap the bridge die 240. In the present specification, overlapping may refer to overlapping in a direction (for example, a Z-direction), perpendicular to the upper surface of the lower insulating layer 211.

Upper surfaces of the external redistribution layers 213 may be in contact with first bonding pads 223. A width of an upper surface of each of the external redistribution layers 213 may be less than a width of each of the first bonding pads 223. Each of the external redistribution layers 213 may have an inclined side surface such that a width thereof increases as a level thereof decreases. The external redistribution layers 213 may have a linear shape extending in the horizontal direction (X-direction or Y-direction). A side cross-section of each of the external redistribution layers 213 may have a trapezoidal shape having an upper side shorter than a lower side thereof. Each of the external redistribution layers 213 may include an external conductive layer 213b and an external seed layer 213a disposed between the external conductive layer 213b and the lower insulating layer 211. The external seed layer 213a may cover a lower surface of the external conductive layer 213b. A side surface of the external conductive layer 213b may be in contact with the encapsulant 250. In some example embodiments, the external seed layer 213a may include, e.g., copper (Cu), titanium (Ti), and/or an alloy thereof, and the external conductive layer 213b may include copper (Cu).

The connection redistribution layers 214 may be disposed on the upper surface of the lower insulating layer 211, may overlap the bridge die 240, and may be connected to the bridge die 240. The upper surfaces of the connection redistribution layers 214 may be in contact with second bonding pads 224. A width of an upper surface of each of the connection redistribution layers 214 may be less than a width of each of the second bonding pads 224. A planar cross-section of each of the connection redistribution layers 214 may be a circular shape, an oval shape, a polygonal shape, and/or the like. The connection redistribution layers 214 may be connected to the bridge die 240 through the second bonding pads 224. The connection redistribution layers 214 may overlap the bridge die 240. The connection redistribution layers 214 may include a connection portion 214_2 having an increasing width as a level thereof decreases, and an extension portion 214_1 having a decreasing width as a level thereof decreases. The connection redistribution layers 214 may have a step portion between a side surface of the connection portion 214_2 and a side surface of the extension portion 214_1. A portion of a lower portion of the connection portion 214_2 may be in contact with the upper surface of the lower insulating layer 211.

An upper surface of the connection portion 214_2 may be in contact with the second bonding pads 224. Each of the connection redistribution layers 214 may include a connection conductive layer 214b and a connection seed layer 214a disposed between the connection conductive layer 214b and the lower insulating layer 211. The connection seed layer 214a may be included in a side surface and a lower surface of the extension portion 214_1, and may be included in a portion of a lower portion of the connection portion 214_2. The connection seed layer 214a may cover a side surface and a lower surface of the connection conductive layer 214b in the lower insulating layer 211. The side surface of the external conductive layer 213b may be in contact with the encapsulant 250. In some example embodiments, the external seed layer 213a may include, e.g., copper (Cu), titanium (Ti), and/or alloys thereof, and the external conductive layer 213b may include copper (Cu).

The UBM structures 217 may be spaced apart from the lower redistribution layers 215, and may pass through the lower insulating layer 211. The UBM structures 217 may be deposited as to not overlap the bridge die 240, but may overlap the conductive posts 230. An upper surface of each of the UBM structures 217 may be in contact with a third bonding pad 227. A width of the upper surface of each of the UBM structures 217 may be less than a width of the third bonding pad 227. A planar cross-section of each of the UBM structures 217 may have a circular shape, an oval shape, or a polygonal shape. A lower surface of each of the UBM structures 217 may be coplanar with the lower surface of the lower insulating layer 211, and may be in contact with a lower connection pad 270.

Each of the UBM structures 217 may include a bonding portion 217_3 in contact with the third bonding pad 227, a pad portion 217_2 connected to the bonding portion 217_3 below the bonding portion 217_3, the pad portion 217_2 disposed in the lower insulating layer 211, and a via portion 217_1 connected to the pad portion 217_2 below the pad portion 217_2. The bonding portion 217_3 may be defined as a portion having an increasing width as a level of the UBM structure 217 decreases. Each of the UBM structures 217 may have a step portion between a side surface of the bonding portion 217_3 and a side surface of the pad portion 217_2, and between the side surface of the pad portion 217_2 and a side surface of the via portion 217_1. A boundary between the side surface of the bonding portion 217_3 and the side surface of the pad portion 217_2 may be positioned on a level the same height as or lower than that of the upper surface of the lower insulating layer 211. A width of the bonding portion 217_3 may increase as a level thereof decreases, and a width of each of the pad portion 217_2 and the via portion 217_1 may decrease as a level thereof decreases. A maximum width of the bonding portion 217_3 may be greater than a maximum width of the pad portion 217_2. In some example embodiments, the maximum width of the bonding portion 217_3 may be a maximum width of the UBM structure 217. A portion of the UBM structure 217 having the maximum width may be defined as a first portion. The first portion may be positioned on a level closer to the upper surface of the lower insulating layer 211 than to an upper surface of the UBM structure 217. The first portion may be positioned on a level at the same height as or lower than that of the upper surface of the lower insulating layer 211.

The UBM structure 217 may include a second portion on the first portion, and a third portion below the first portion. In the second portion, the width of the UBM structure 217 may decrease as a level thereof increases. In the third portion, the width of the UBM structure 217 may decrease as a level thereof decreases. At least one step portion may be present on a side surface of the UBM structure 217, between the second portion and the third portion. A lower surface of the UBM structure 217 (e.g., a lower surface of the via portion 217_1) may be coplanar with the lower surface of the lower insulating layer 211. In some example embodiments, a portion of the UBM structure 217 having a maximum width may be a lower portion of the bonding portion 217_3. A portion of the bonding portion 217_3 may be in contact with the upper surface of the lower insulating layer 211.

Each of the UBM structures 217 may include a UBM conductive layer 217b and a UBM seed layer 217a disposed between the UBM conductive layer 217b and the lower insulating layer 211. The UBM seed layer 217a may be included in a side surface and a lower surface of the via portion 217_1 and a portion of a side surface and a lower surface of the pad portion 217_2 and a portion (interface with the lower insulating layer 211) of a lower surface of the bonding portion 217_3. In some example embodiments, the UBM seed layer 217a may include, e.g., copper (Cu), titanium (Ti), and/or an alloy thereof, and the UBM conductive layer 217b may include copper (Cu).

The bonding pads 220 may be positioned on an upper surface of a portion of the lower redistribution layers 215 and upper surfaces of the UBM structures 217. The bonding pads 220 may disposed as to not be on the internal redistribution layers 212, but may be disposed to be spaced apart from the upper surface of the lower insulating layer 211. The bonding pads 220 may be a component used as an etching mask in a process of forming the external redistribution layers 213, the connection redistribution layers 214, and the UBM structures 217. In such a manner, a width of an upper surface of each of the external redistribution layers 213, the connection redistribution layers 214, and the UBM structures 217, positioned below each of the bonding pads 220, may be formed to be less than a width of each of the bonding pads 220. The bonding pads 220 may include first bonding pads 223 respectively disposed on upper surfaces of the external redistribution layers 213, second bonding pads 224 respectively disposed on upper surfaces of the connection redistribution layers 214, and third bonding pads 227 respectively disposed on upper surfaces of the UBM structures 217. Each of the first bonding pads 223 may have a linear shape extending along each of the external redistribution layers 213 extending in the horizontal direction.

A planar cross-section of each of the second bonding pads 224 and the third bonding pads 227 may have a circular shape, an oval shape, a polygonal shape, and/or the like. An upper surface of each of the first bonding pads 223 may be covered by the encapsulant 250. Each of the first bonding pads 223 may have a width greater than a width of the upper surface of each of the external redistribution layers 213. An upper surface of each of the second bonding pads 224 may be in contact with the bridge die 240. An upper surface of each of the second bonding pads 224 may be in contact with a connection solder 228 of the bridge die 240. Each of the second bonding pads 224 may have a width greater than a width of an upper surface of each of the connection redistribution layers 214. Upper surfaces of the third bonding pads 227 may be in contact with the conductive posts 230. Each of the third bonding pads 227 may have a width greater than a width of an upper surface of each of the UBM structures 217. Each of the bonding pads 220 may include a plurality of conductive layers. For example, each of the bonding pads 220 may include a first bonding conductive layer 227a and a second bonding conductive layer 22b on the first bonding conductive layer. In some example embodiments, the first bonding conductive layer 227a may include nickel (Ni) and/or an alloy including nickel (Ni), and the second bonding conductive layer 227b may include gold (Au) and/or an alloy including gold (Au).

The conductive posts 230 may pass through the encapsulant 250, and may electrically connect the lower redistribution structure 210 and the upper redistribution structure 260 to each other. The conductive posts 230 may extend in the vertical direction (for example, a Z-direction) in the encapsulant 250. A width of each of the conductive posts 230 may be less than a width of each of the third bonding pads 227. In some example embodiments, a width of a lower surface of each of the conductive posts 230 may be less than a width of the upper surface of the UBM structure 217 (e.g., an upper surface of the bonding portion 217_3). A planar cross-section of each of the conductive posts 230 may have a circular shape, but the present inventive concepts is not limited thereto. For example, a planar cross-section of each of the conductive posts 230 may have an oval shape or a polygonal shape. Upper surfaces of the conductive posts 230 may be coplanar with an upper surface of the encapsulant 250. The conductive posts 230 may overlap the UBM structures 217, respectively. The conductive posts 230 may be electrically connected to the UBM structure 217 through the third bonding pads 227. The conductive posts 230 may include a zero bandgap conductive material, for example, a metal including copper (Cu), aluminum (Al), silver (Ag), tin (Sn), gold (Au), nickel (Ni), lead (Pb), titanium (Ti), and/or alloys thereof.

The bridge die 240 may be disposed on the lower redistribution structure 210. The bridge die 240 may at least partially overlap the semiconductor chips 300. Complex signal lines of the semiconductor chips 300 may be connected to each other by the bridge die 240. As the interposer substrate 200 includes the bridge die 240, a semiconductor package may have an improved degree of integration and improved reliability. The bridge die 240 may include through-vias 243, a bridge body 245, connection pillars 247, and connection solders 248.

The bridge body 245 may include ceramic, glass, a semiconductor, and/or the like. For example, the bridge body 245 may be formed based on an active wafer, and may include silicon (Si), germanium (Ge), gallium arsenide (GaAs), and/or the like. The bridge body 245 may include an interconnection circuit (not illustrated) therein. The semiconductor chips 300 may transfer the complex signal lines to each other through interconnection circuits.

The through-vias 243 may pass through the bridge body 245, and may electrically connect connection pillars 247 disposed on an upper surface and a lower surface of the bridge body 245 to each other. The through-via 243 may be a through-silicon via passing through the bridge body 245 in the vertical direction (for example, a Z-direction). The through-via 243 may transfer an electrical signal between the semiconductor chips 300, together with the interconnection circuit in the bridge body 245. The through-vias 243 may include a conductive material (e.g., a zero bandgap conductive material), for example, tungsten (W), titanium (Ti), aluminum (Al), copper (Cu), and/or an alloy thereof. In some example embodiments, the through-vias 243 may include a barrier film disposed on a contact surface with the bridge body 245. The barrier film may include an insulating barrier film and/or a conductive barrier film. The insulating barrier film may be formed of an oxide film, a nitride film, a carbonized film, a polymer, and/or combinations thereof. The conductive barrier film may include, for example, a metal-based compound such as tungsten nitride (WN), titanium nitride (TiN), or tantalum nitride (TaN).

The connection pillars 247 may be disposed on the upper and lower surfaces of the bridge body 245, and may be connected to each other by the through-vias 243. The connection solders 248 may be in contact with the second bonding pads 224 under the connection pillars 247 on the lower surfaces of the bridge body 245. The connection pillars 247 may include copper (Cu) and/or an alloy of copper (Cu), and the connection solders 248 may include a low melting point metal, for example, tin (Sn) and/or an alloy including tin (Sn). In some example embodiments, the bridge die 240 may include only one of the connection pillars 247 and the connection solders 248. In some example embodiments, an underfill layer may be disposed between the bridge die 240 and the lower redistribution structure 210. The underfill layer may have a capillary underfill (CUF) structure, but example embodiments are not limited thereto. The underfill layer may have a molded underfill (MUF) structure integrated with the encapsulant 250.

The encapsulant 250 may be disposed on the lower redistribution structure 210, and may cover at least a portion of each of the lower redistribution layers 215, the UBM structures 217, the bonding pads 220, the conductive posts 230, and the bridge die 240. The encapsulant 250 may include, for example, a thermosetting resin such as an epoxy resin, a thermoplastic resin such as polyimide, or a prepreg, an ABF, FR-4, BT, an epoxy molding compound (EMC) and/or the like. The encapsulant 250 may surround the conductive posts 230.

The upper redistribution structure 260 may be disposed on the encapsulant 250, and may include an upper insulating layer 261 and upper redistribution layers 265.

The upper insulating layer 261 may include, for example, a thermosetting resin such as an epoxy resin, a thermoplastic resin such as polyimide, or a resin (for example, a prepreg, an ABF, FR-4, BT, etc.) in which the thermosetting resin or the thermoplastic resin is impregnated with an inorganic filler or the like. In some example embodiments, an organic material may be included. For example, the upper insulating layer 261 may include a photosensitive polymer. The photosensitive polymer may include, for example, at least one of photosensitive polyimide, polybenzoxazole, a phenol-based polymer, and a benzocyclobutene-based polymer. In some example embodiments, the upper insulating layer 261 may include a plurality of insulating layers, stacked in a vertical direction (for example, a Z-direction). Depending on a process, the plurality of insulating layers (not illustrated) may have unclear boundaries therebetween.

The upper redistribution layers 265 may be disposed on and in the upper insulating layer 261. The upper redistribution layer 265 may include a zero bandgap conductive material, for example, a metal including copper (Cu), aluminum (Al), silver (Ag), tin (Sn), gold (Au), nickel (Ni), lead (Pb), titanium (Ti), and/or alloys thereof. The upper redistribution layer 265 may include a ground pattern, a power pattern, and a signal pattern depending on a design thereof. The number of the upper redistribution layers 265 may be greater than or less than the number of redistribution layers illustrated in the drawings. In some example embodiments, a barrier film may be formed on a pad portion of an uppermost upper redistribution layer 265. The barrier film may include, for example, nickel (Ni), gold (Au), and/or an alloy thereof. The upper redistribution layers 265 on the upper insulating layer 261 may be connected to the semiconductor chips 300.

The lower connection pads 270 and the connection conductors 280 may be disposed below a lower surface of the lower insulating layer 211, and may be directly connected to the upper pads 120 of the package substrate 100. A portion of the lower connection pads 270 may be in contact with a lower surface of the UBM structure 217. The lower connection pads 270 may include at least one of aluminum (Al), copper (Cu), nickel (Ni), tungsten (W), platinum (Pt), and gold (Au), but the present inventive concepts are not limited thereto. The connection conductors 280 may include, for example, a solder ball. The solder ball may include tin (Sn), bismuth (Bi), lead (Pb), silver (Ag), and/or alloys thereof.

The semiconductor chips 300 may be disposed on the interposer substrate 200. The semiconductor chips 300 may be electrically connected to the package substrate 100 through the interposer substrate 200. Each of the semiconductor chips 300 may include a logic chip including a central processing unit (CPU), a graphics processing unit (GPU), a field programmable gate array (FPGA), a digital signal processor (DSP), a cryptographic processor, a microprocessor, a microcontroller, an analog-to-digital converter, or an application-specific IC (ASIC), and/or a memory chip including a volatile memory such as a dynamic RAM (DRAM) or a static RAM (SRAM), and a non-volatile memory such as a phase change RAM (PRAM), a magnetic RAM (MRAM), a resistive RAM (RRAM), or a flash memory.

The semiconductor chips 300 may include a first semiconductor chip 300a and a second semiconductor chip 300b, disposed on the interposer substrate 200 to be parallel to each other. In some example embodiments, the semiconductor chips 300 may include semiconductor chips vertically stacked on the interposer substrate 200. The first semiconductor chip 300a and the second semiconductor chip 300b may include different types of semiconductor chips. For example, the first semiconductor chip 300a may include a logic chip, and the second semiconductor chip 300b may include a memory chip, but the present inventive concepts are not limited thereto. In at least some embodiments, the second semiconductor chip 300b may be provided as a high-capacity memory device such as a high-bandwidth memory (HBM). The number of semiconductor chips 300 may be greater than that illustrated in the drawing.

In the following description, descriptions overlapping those described with reference to FIGS. 1 to 4 may be omitted.

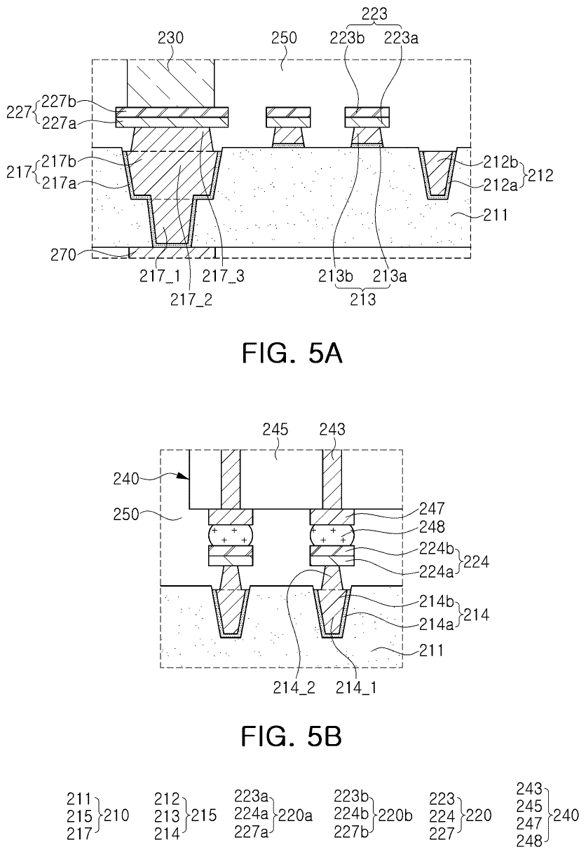

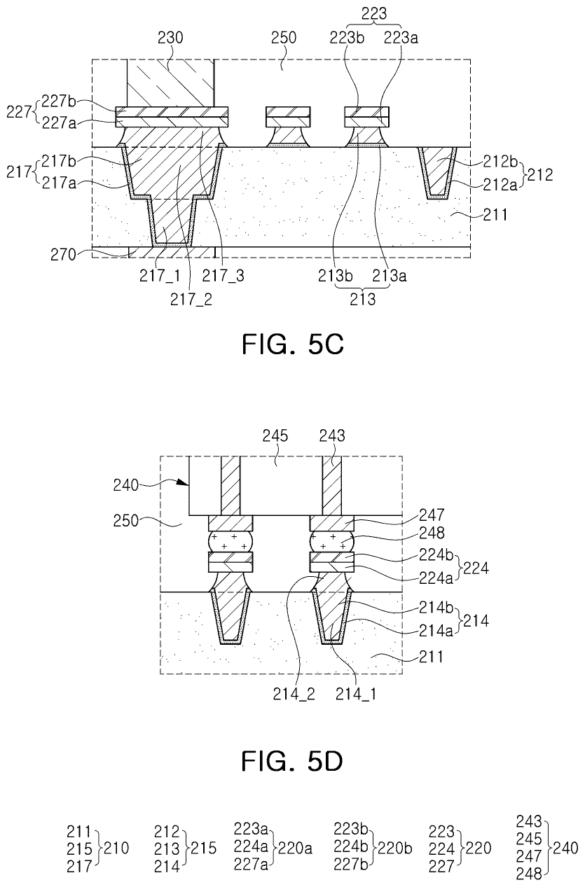

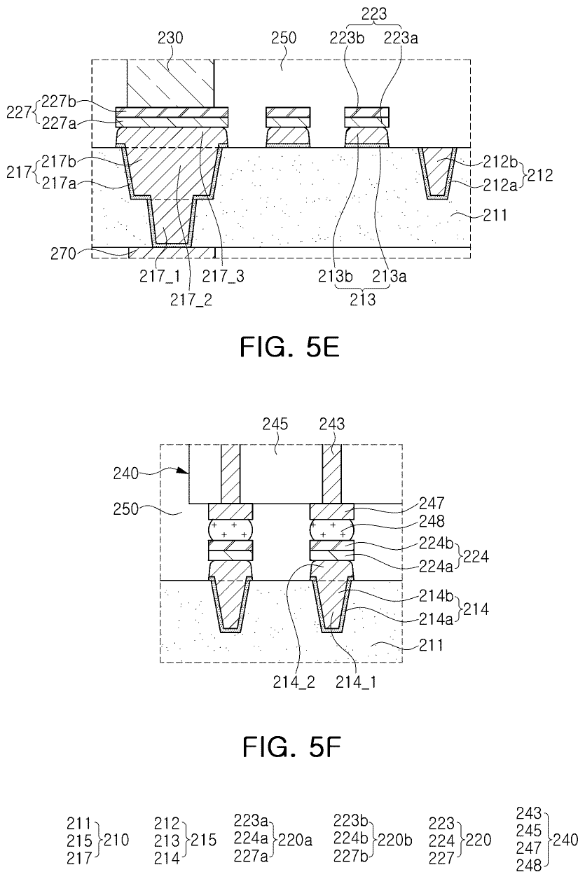

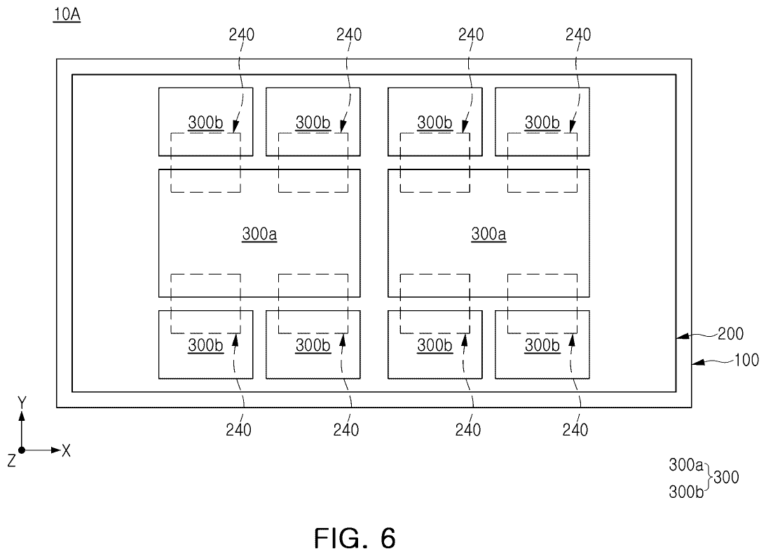

FIGS. 5A to 5F are schematic cross-sectional enlarged views of a semiconductor package according to example embodiments. FIGS. 5A to 5F are enlarged views of regions corresponding to regions “A” and “B” of FIGS. 3A and 3B.

Referring to FIGS. 5A and 5B, unlike FIGS. 3A and 3B, a lower portion of the bonding portion 217_3, having an increasing width as a level thereof decreases, may be positioned on a level, lower than that of an upper surface of the lower insulating layer 211. The bonding portion 217_3 may be spaced apart from the lower insulating layer 211. An upper end of the UBM seed layer 217a may be positioned on a level, lower than that of the upper surface of the lower insulating layer 211. The UBM seed layer 217a may be disposed on a side surface of the pad portion 217_2, a side surface of the via portion 217_1, and a lower surface of the via portion 217_1. A maximum width of the bonding portion 217_3 may be less than a maximum width of the pad portion 217_2. An upper surface of each of the internal redistribution layers 212 may be positioned on a level, lower than that of the upper surface of the lower insulating layer 211. A lower portion of the connection portion 214_2, having an increasing width as a level thereof decreases, may be positioned on a level, lower than that of the upper surface of the lower insulating layer 211. The connection portion 214_2 may be spaced apart from the lower insulating layer 211. The connection redistribution layers 214 may be formed using a process, the same as that of the UBM structure 217, and thus may have a form partially similar to that of the UBM structure 217. The lower redistribution layers 215 and the UBM structure 217 may have various shapes according to a degree of etching and an etching method in a process.

Referring to FIGS. 5C and 5D, unlike FIGS. 3A and 3B, at least a portion of a side surface of the bonding portion 217_3 and a side surface of each of the external redistribution layers 213 may be a curved surface. The side surface of the bonding portion 217_3 and the side surface of each of the external redistribution layers 213 may have a decreasing inclination as levels thereof decrease.

Referring to FIGS. 5E and 5F, unlike FIGS. 5C and 5B, the side surface of the bonding portion 217_3 and the side surface of each of the external redistribution layers 213 may have an increasing inclination as the levels thereof decrease.

Features of the example embodiments of FIGS. 3A, 3B, and 5A to 5F may be combined with each other within a compatible range. For example, even when the side shapes of the bonding portion 217_3 and the connection portion 214_2 are curved surfaces as illustrated in FIGS. 5B and 5C, the maximum width of the bonding portion 217_3 may be disposed to be less than a maximum width of the connection portion 214_2, as illustrated in FIG. 5A.

FIG. 6 is a schematic plan view of a semiconductor package according to some example embodiments.

Referring to FIG. 6, unlike the semiconductor package 10 of FIG. 1, a semiconductor package 10A may include a plurality of first semiconductor chips 300a and a plurality of second semiconductor chips 300b, and may include a plurality of bridge dies 240. In some example embodiments, the plurality of second semiconductor chips 300b may be disposed around one first semiconductor chip 300a. In some example embodiments, the bridge dies 240 may electrically connect the first semiconductor chip 300a and the second semiconductor chips 300b, adjacent to the first semiconductor chip 300a, to each other to transmit an electrical signal. In some example embodiments, the first semiconductor chip 300a may include a logic chip, and the second semiconductor chip 300b may include a memory chip. In some example embodiments, four second semiconductor chips 300b including a memory chip may be disposed to be adjacent to one first semiconductor chip 300a including a logic chip. In some example embodiments, unlike that illustrated, a portion of the bridge dies 240 may be simultaneously disposed to overlap adjacent first semiconductor chips 300a. The type, number, arrangement, or the like of the semiconductor chips 300 including the first semiconductor chips 300a and the second semiconductor chips 300b may be changed in various manners.

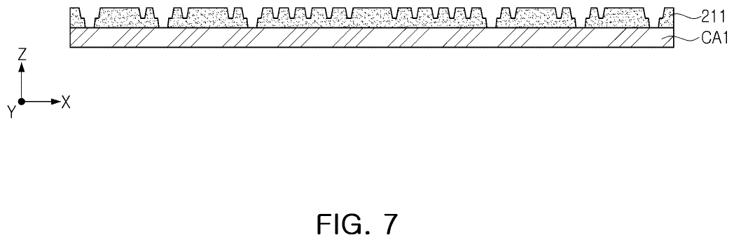

FIGS. 7, 8A, 9, 10A, 11A, 12, 13A, 14A, 15, 16, 17, 18, and 19 are cross-sectional views of sequential processes in a method of manufacturing a semiconductor package according to some example embodiments. FIGS. 7, 8A, 9, FIG. 10A, FIG. 11A, FIG. 12, FIG. 13A, FIG. 15, FIG. 16, FIG. 17, FIG. 18, and FIG. 19 illustrate a region corresponding to FIG. 2.

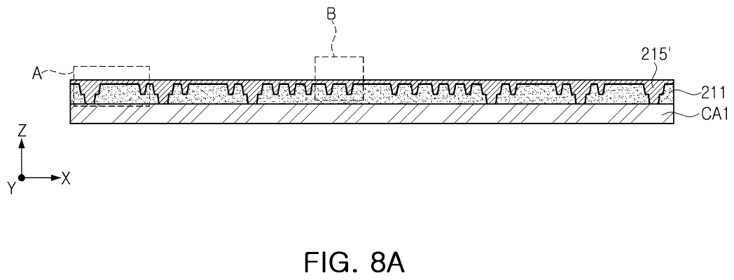

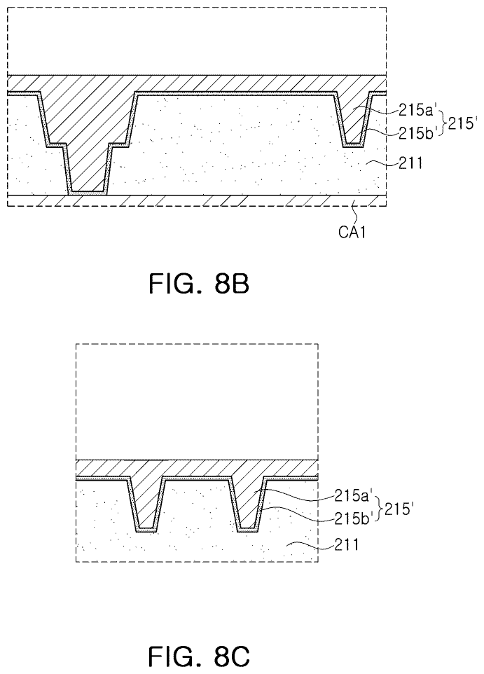

FIGS. 8B, 8C, 10B, 10C, 11B, 11C, 13B, 13C, 14B, and 14C are cross-sectional partially enlarged views of sequential processes in a method of manufacturing a semiconductor package according to example embodiments. FIGS. 8B, 8C, 10B, 10C, 11B, 11C, 13B, 13C, 14B, and 14C are enlarged views of regions “A” and “B” of FIGS. 8A, 10A, 11A, 13A, and 14A, respectively.

Referring to FIG. 7, a lower insulating layer 211 may be formed on a first carrier CA1. In the first carrier CA1, for example, a polymer layer including a curable resin, and a metal layer including nickel (Ni) or titanium (Ti) may be sequentially coated on a copper clad laminate (CCL). The lower insulating layer 211 may be formed by coating an insulating material on the first carrier CA1 and then performing an etching process using etchant exposure or a laser. In some example embodiments, the lower insulating layer 211 may be formed by repeatedly coating and curing a photosensitive material, for example, a photoimageable dielectric (PID). A space in which the internal redistribution layers 212, the connection redistribution layers 214, and the UBM structures 217 of FIG. 1 to FIG. 4 are to be disposed may be formed using the exposure and etching processes. The space may be simultaneously formed using a dual damascene method. With respect to a space in which the UBM structures 217 are to be disposed and a space in which the internal redistribution layers 212 and the connection redistribution layers 214 are to be disposed, a degree of etching may be differently adjusted by varying etching strength. For example, when etching is performed using exposure, 100% of exposure may be performed on a space in which the UBM structures 217 are to be formed, and 20% of exposure may be performed on a space in which the internal redistribution layers 212. For another example, when the lower insulating layer 211 is etched using a laser, each space may be etched differently by adjusting a laser pulse. In the space in which the UBM structures 217 are to be formed, an upper surface of the first carrier CA1 may be partially exposed.

Referring to FIG. 8A to 8C, preliminary redistribution layers 215′ may be formed on the lower insulating layer 211. The forming the preliminary redistribution layers 215′ may including sequentially forming a preliminary seed layer 215a′ and a preliminary conductive layer 215b′. In some example embodiments, the preliminary seed layer 215a′ may be titanium (Ti) and/or copper (Cu)-deposited on the lower insulating layer 211 using a method such as sputtering, a conductive material such as copper (Cu) may be plated on the preliminary seed layer 215a′ to form the preliminary conductive layer 215b′. The preliminary seed layer 215a′ may conformally cover the lower insulating layer 211, and the preliminary conductive layer 215b′ may be formed to fill an etched space of the lower insulating layer 211 and cover an upper surface of the lower insulating layer 211.

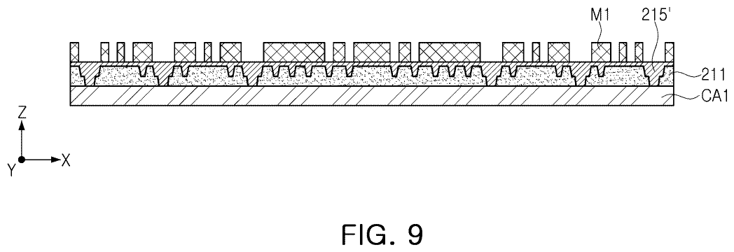

Referring to FIG. 9, a first mask M1 may be formed on the preliminary redistribution layers 215′. The first mask M1 may be formed to expose a space in which the bonding pads 220 of FIGS. 1 to 5 are to be formed. The first mask M1 may be formed to partially expose the preliminary conductive layer 215b′ using exposure and development after a photoresist material is coated on the preliminary conductive layer 215b′.

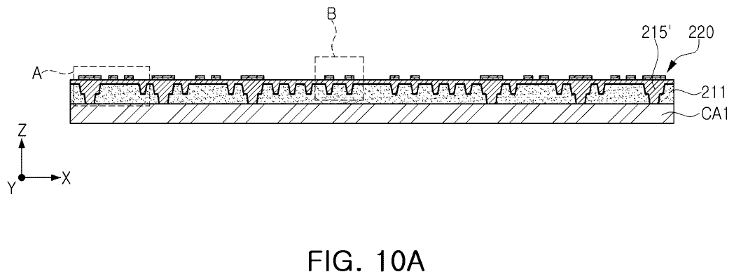

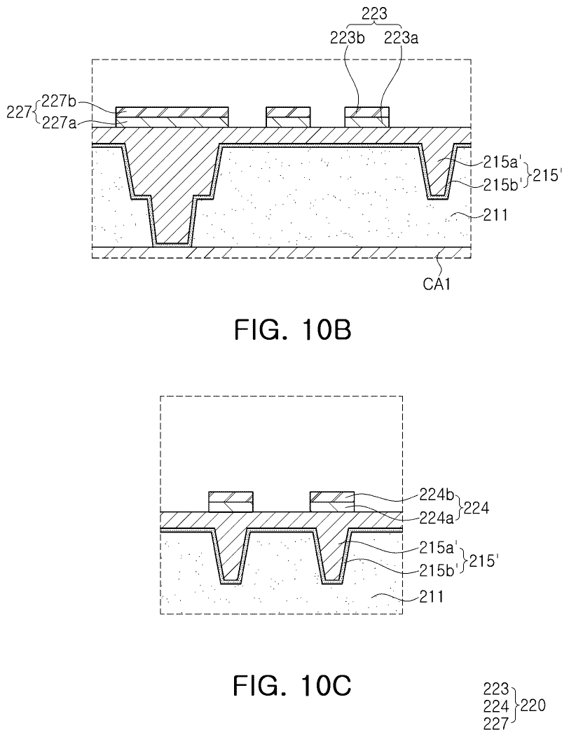

Referring to FIGS. 10A to 10C, bonding pads 220 may be formed on the preliminary redistribution layers 215′, and the first mask M1 may be removed. The bonding pads 220 may be formed to cover upper surfaces of the preliminary redistribution layers 215′ exposed by the first mask M1. The bonding pads 220 may include a plurality of conductive layers. In some example embodiments, a nickel (Ni) layer and a gold (Au) layer may be sequentially formed to form the bonding pads 220.

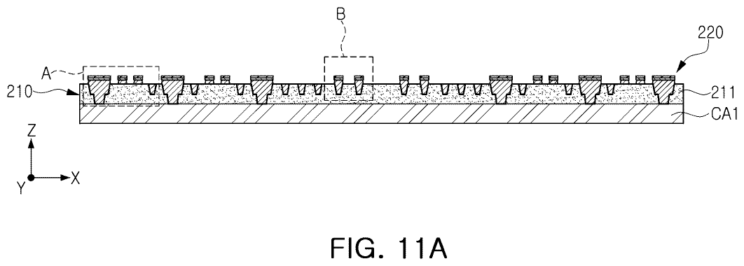

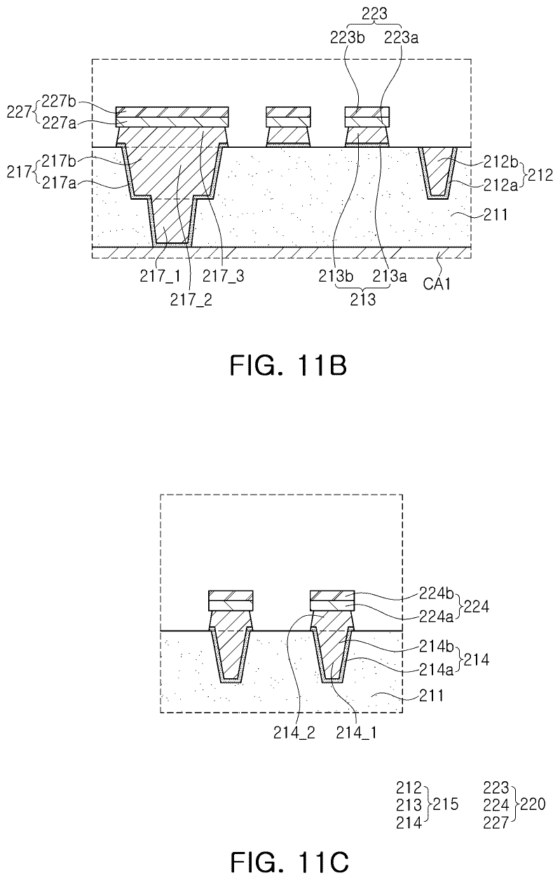

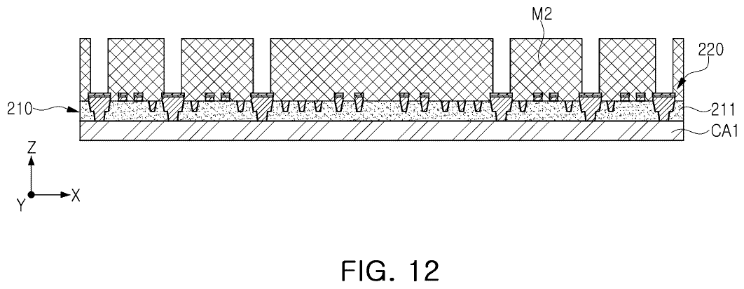

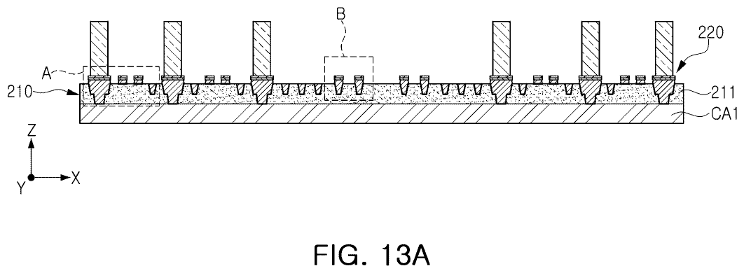

Referring to FIGS. 11A to 11C, the preliminary redistribution layers 215′ may be partially etched to form lower redistribution layers 215, including internal redistribution layers 212, external redistribution layers 213, and connection redistribution layers 214, and a UBM structure 217. A portion of the preliminary redistribution layers 215′ exposed from the bonding pads 220 may be etched using the bonding pads 220 as an etching mask. In some example embodiments, the present operation may be performed using an isotropic wet etching process. For example, an etching material including, e.g., CuCl₂ may be used, and/or an etching material obtained by mixing H₂O₂ and H₂SO₄ may be used. Various example embodiments of FIGS. 3, 5A to 5F may be formed according to an etching method, a degree of etching, and/or the like of the present operation. In some example embodiments, as an isotropic wet etching process using the bonding pads 220 as an etching mask is performed in the present operation, the external redistribution layers 213, connection portions 214_2 of the connection redistribution layers 214, and a bonding portion 217_3 of the UBM structure 217 may be formed to have a shape having an increasing width as a level thereof decreases.

In the present inventive concepts, a dual damascene method may be used to etch the lower insulating layer 211, and an isotropic wet etching process (e.g., a tenting method)s may be used to etch the preliminary redistribution layers 215′. Each of the lower redistribution layers 215 and the UBM structures 217 may have a flat upper surface using such a process, and may be stably coupled to other components disposed on the upper surface thereof. In addition, the exposure and etching processes performed to form the UBM structure 217 and the lower redistribution layers 215 may be reduced and/or minimized (e.g., compared to comparative examples), thereby providing a semiconductor package having a simplified process and improved reliability.

Referring to FIG. 12, a second mask M2 may be formed on the lower redistribution structure 210. The second mask M2 may be formed to expose a space in which the conductive posts 230 of FIGS. 1 to 5 are to be formed. The second mask M2 may be formed to partially expose upper surfaces of the third bonding pads 227 on the UBM structure 217 using exposure and development after a photoresist material is coated on the lower redistribution structure 210.

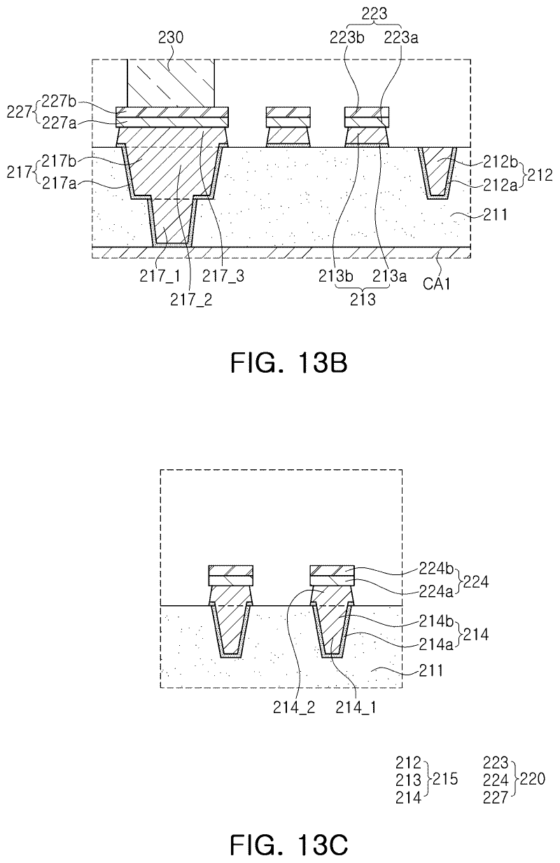

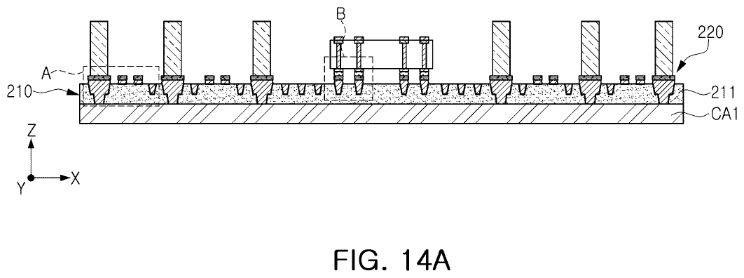

Referring to FIGS. 13A to 13C, conductive posts 230 may be formed on the third bonding pads 227 on the UBM structure 217, and the second mask M2 may be removed. The conductive posts 230 may be formed by plating, for example, copper (Cu). Upper surfaces of the conductive posts 230 may be formed to be positioned on a level, higher than that of the upper surfaces of the conductive posts 230 of FIG. 2.

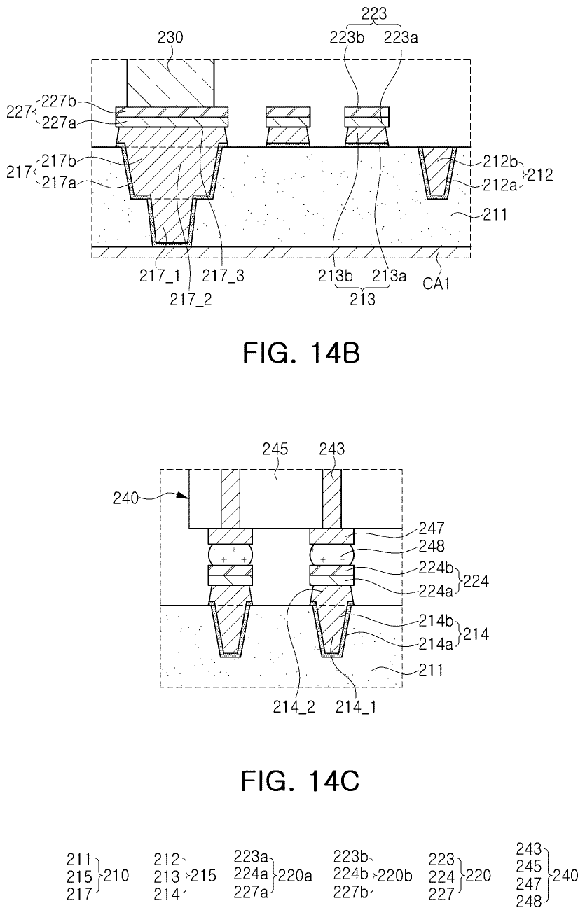

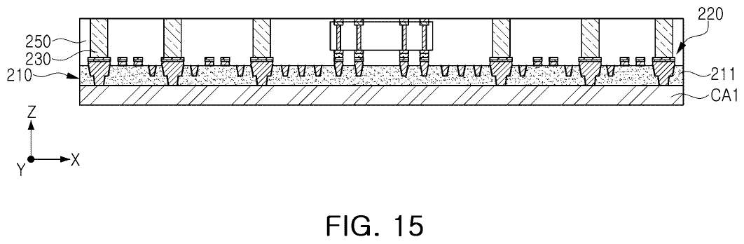

Referring to FIGS. 14A to 14C, a bridge die 240 may be disposed on the lower redistribution structure 210. The bridge die 240 may be disposed on the second bonding pads 224 on the connection redistribution layers 214. An upper end of the bridge die 240 may be positioned on a level, lower than that of the upper surfaces of the conductive posts 230.

Referring to FIG. 15, an encapsulant 250 may be formed, and the conductive posts 230 and the encapsulant 250 may be partially removed from upper surfaces thereof. The encapsulant 250 may be formed by coating and curing an EMC, for example. The encapsulant 250 may be formed to cover the bridge die 240 up to a level higher than that of an upper end of the bridge die 240, and then may be formed by partially removing the encapsulant 250 and the conductive posts 230 from the upper surfaces thereof. Accordingly, the upper surfaces of the conductive posts 230 and upper surfaces of the connection pillars 247, positioned on the bridge die 240, may be coplanar with each other, and may be exposed from the encapsulant 250.

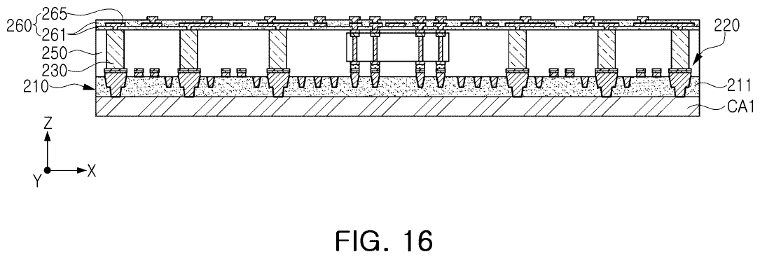

Referring to FIG. 16, an upper redistribution structure 260 may be formed on the encapsulant 250. The upper redistribution structure 260 may be formed using a process, partially similar to that of the lower redistribution structure 210. The upper insulating layer 261 may be formed by sequentially coating and curing a photosensitive material, for example, a PID. The upper redistribution layers 265 may be formed by performing exposure and development processes to form a via hole passing through the upper insulating layer 261, and patterning a metal material on the upper insulating layer 261 using a plating process. The upper redistribution layers 265 may be electrically connected to the conductive posts 230 and the bridge die 240.

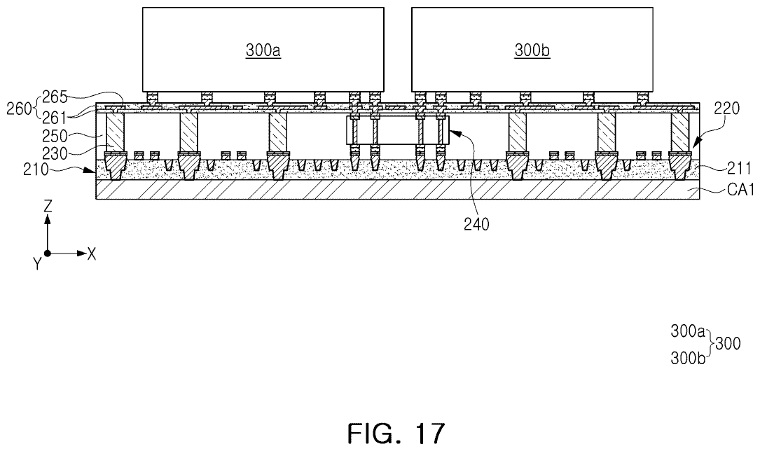

Referring to FIG. 17, semiconductor chips 300 may be disposed on the upper redistribution structure 260. The semiconductor chips 300 may be mounted to be electrically connected to the upper redistribution layers 265. The mounted semiconductor chips 300 may transmit a complex electrical signal to each other through the bridge die 240.

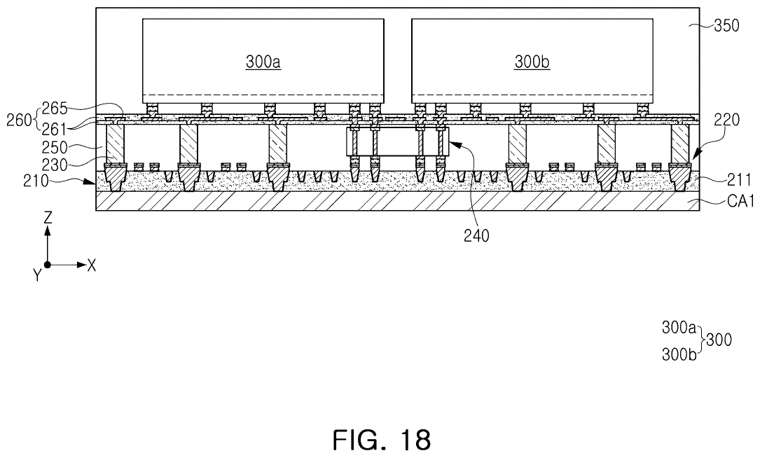

Referring to FIG. 18, an upper encapsulant 350, covering the semiconductor chips 300, may be formed on the upper redistribution structure 260. The upper encapsulant 350 may be formed by, for example, coating and curing an EMC. In some example embodiments, the upper encapsulant 350 may be formed to cover upper surfaces of the semiconductor chips 300, but the present inventive concepts are not limited thereto. For example, the upper encapsulant 350 may be partially etched from an upper portion thereof such that the upper surfaces of the semiconductor chips 300 are exposed. In some example embodiments, the upper encapsulant 350 may not be formed.

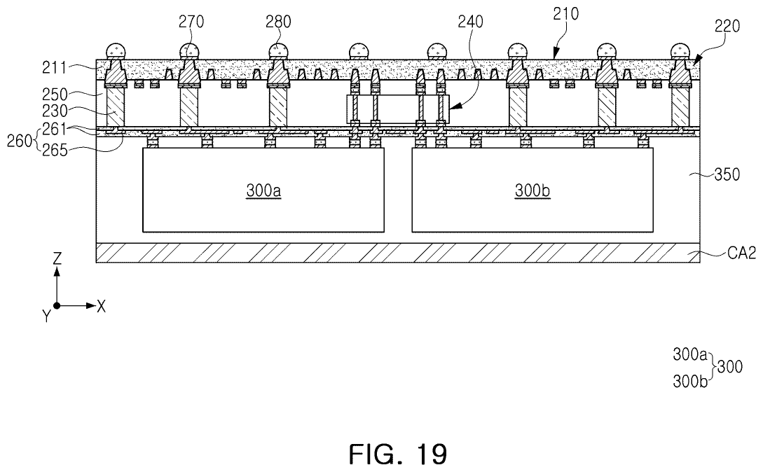

Referring to FIG. 19, a second carrier CA2 may be disposed on the upper encapsulant, and the first carrier CA1 may be removed to form lower connection pads 270 and connection conductors 280 on an exposed upper surface (based on FIG. 19) of the lower redistribution structure 210. A portion of the lower connection pads 270 may be connected to the UBM structure 217 to be in direct contact with the UBM structure 217.

Referring to FIG. 19 together with FIG. 2, an interposer substrate 200 may be disposed on the package substrate 100. The semiconductor chips 300 transmit an electrical signal to each other through the interposer substrate 200, and may also be electrically connected to the package substrate 100.

According to example embodiments of the present inventive concepts, a semiconductor package may include two different types of methods in the process of forming an interposer substrate including a bridge die (for example, a semiconductor bridge) connecting individual chips to each other, and thus may have a simplified process and improved reliability.

While example embodiments have been shown and described above, it will be apparent to those skilled in the art that modifications and variations could be made without departing from the scope of the present inventive concepts as defined by the appended claims.

What is claimed is:

1. A semiconductor package comprising:
a lower redistribution structure including a lower insulating layer, an under bump metallization (UBM) structure, and lower redistribution layers, the UBM structure passing through the lower insulating layer, and the lower redistribution layers on and in the lower insulating layer;
a bridge die above and electrically connected to the lower redistribution layers;
a bonding pad above the UBM structure;
an encapsulant above the lower insulating layer and covering at least a portion of each of the bridge die, the lower redistribution layers, the UBM structure, and the bonding pad; and
a conductive post passing through the encapsulant, the conductive post above and connected to the bonding pad,
wherein the UBM structure includes
a bonding portion in contact with the bonding pad, the bonding portion having an increasing width with distance from the bonding pad,
a pad portion below and connected to the bonding portion, and
a via portion below and connected to the pad portion,
a width of an upper surface of the bonding portion is less than a width of the bonding pad, and
a width of a lower surface of the conductive post is less than a width of the bonding pad.

2. The semiconductor package of claim 1, wherein widths of the pad portion and the via portion decrease with distance from the bonding pad.

3. The semiconductor package of claim 1, wherein, a lower surface of the via portion is coplanar with a lower surface of the lower insulating layer.

4. The semiconductor package of claim 1, wherein, in a cross-sectional view, the UBM structure has step portions between a side surface of the bonding portion and a side surface of the pad portion and between the side surface of the pad portion and a side surface of the via portion.

5. The semiconductor package of claim 4, wherein the step portion between the side surface of the bonding portion and the side surface of the pad portion is at a same or lower level than that of an upper surface of the lower insulating layer.

6. The semiconductor package of claim 1, wherein the width of the lower surface of the conductive post is less than the width of the upper surface of the bonding portion.

7. The semiconductor package of claim 1, wherein the UBM structure further includes a UBM conductive layer and a UBM seed layer between the UBM conductive layer and the lower insulating layer.

8. The semiconductor package of claim 7, wherein
a maximum width of the bonding portion is greater than a maximum width of the pad portion, and
the UBM seed layer is on an interface between the bonding portion and the lower insulating layer, a side surface of the pad portion, a side surface of the via portion, and a lower surface of the via portion.

9. The semiconductor package of claim 7, wherein
a maximum width of the bonding portion is less than a maximum width of the pad portion, and
the UBM seed layer is on a side surface of the pad portion, a side surface of the via portion, and a lower surface of the via portion.

10. The semiconductor package of claim 1, wherein the lower redistribution layers include:
internal redistribution layers in the lower insulating layer;
external redistribution layers on the lower insulating layer, the external redistribution layers spaced apart from the bridge die; and
connection redistribution layers overlapping and connected to the bridge die.

11. The semiconductor package of claim 10, wherein each of the connection redistribution layers includes:
a connection portion having an increasing width with distance from the bridge die; and
an extension portion below the connection portion, the extension portion having a decreasing width with distance from the bridge die.

12. The semiconductor package of claim 10, wherein each of the connection redistribution layers includes a connection conductive layer and a connection seed layer, the connection seed layer between the connection conductive layer and the lower insulating layer.

13. A semiconductor package comprising:
a bridge die;
a lower insulating layer below the bridge die;
lower redistribution layers including external redistribution layers, internal redistribution layers, and connection redistribution layers, the external redistribution layers on the lower insulating layer, the internal redistribution layers in the lower insulating layer, and the connection redistribution layers connected to the bridge die; and
an under bump metallization (UBM) structure spaced apart from the bridge die in a horizontal direction, at least portion of the UBM structure passing through the lower insulating layer,
wherein each of the external redistribution layers has a lower surface in contact with an upper surface of the lower insulating layer, and has an increasing width with distance approaching the upper surface of the lower insulating layer, and
each of the internal redistribution layers has an upper surface at a same or lower level as the upper surface of the lower insulating layer, and each of the internal redistribution layers has a decreasing width with distance from the upper surface of the lower insulating layer.

14. The semiconductor package of claim 13, wherein
each of the internal redistribution layers includes an internal conductive layer and an internal seed layer between the internal conductive layer and the lower insulating layer, and
each of the external redistribution layers includes an external conductive layer and an external seed layer between the external conductive layer and the lower insulating layer.

15. The semiconductor package of claim 14, wherein
the internal seed layer covers a side surface and a lower surface of the internal conductive layer, and
the external seed layer covers a lower surface of the external conductive layer.

16. The semiconductor package of claim 13, wherein the external redistribution layers and the UBM structure do not overlap the bridge die in a vertical direction.

17. A semiconductor package comprising:
a package substrate;
semiconductor chips; and
an interposer substrate between the package substrate and the semiconductor chips, the interposer substrate electrically connecting the semiconductor chips to the package substrate and including
a lower redistribution structure including a lower insulating layer and an under bump metallization (UBM) structure passing through the lower insulating layer,
a bridge die on the lower redistribution structure, the bridge die spaced apart from the UBM structure and electrically connected to the semiconductor chips,
an encapsulant on the lower redistribution structure and covering at least a portion of the bridge die and at least a portion of the UBM structure,
an upper redistribution structure on the encapsulant, the upper redistribution structure including upper redistribution layers electrically connected to the semiconductor chips, and
a conductive post passing through the encapsulant, the conductive post electrically connecting the upper redistribution layers and the UBM structure,
wherein the UBM structure includes
a first portion at a level closer to an upper surface of the lower insulating layer than to an upper surface of the UBM structure, the first portion having a maximum width in a horizontal direction,
a second portion above the first portion and having a width decreasing with distance from the first portion, and
a third portion below the first portion and having a width decreasing with distance from the first portion.

18. The semiconductor package of claim 17, wherein the UBM structure has at least one step portion between the second portion and the third portion.

19. The semiconductor package of claim 17, wherein the first portion is at a same or lower level than the upper surface of the lower insulating layer.

20. The semiconductor package of claim 17, wherein
the semiconductor chips include a first semiconductor chip including a logic chip, and a second semiconductor chip including a memory chip, and
the bridge die electrically connects the first semiconductor chip and the second semiconductor chip.
